(19) United States
(12) Patent Application Publication
(10) Pub. No.: US 2014/0140034 A1
(43) Pub. Date: May 22, 2014

(54) POWER CONVERSION APPARATUS

(71) Applicant: DENSO CORPORATION, Kariya-city (JP)

(72) Inventors: Takashi KUSADA, Okazaki-shi (JP); Tetsuya HYAKUTAKE, Nishio-shi (JP); Taijirou MOMOSE, Kariya-shi (JP); Makoto OKAMURA, Nisshin-shi (JP)

(73) Assignee: DENSO CORPORATION, Kariya-city (JP)

(21) Appl. No.: 14/085,856

(22) Filed: Nov. 21, 2013

(30) Foreign Application Priority Data
Nov. 22, 2012 (JP) 2012-256453
Jul. 24, 2013 (JP) 2013-153612

(51) Int. Cl. H05K 5/00

(52) U.S. Cl. CPC H05K 5/0091
USPC 361/820

(57) ABSTRACT

A power conversion apparatus includes at least one semiconductor module including a main electrode terminal, a capacitor including at least one capacitor terminal member connected to the main electrode terminal of the semiconductor module, and an apparatus case housing the semiconductor module and the capacitor. The capacitor includes a capacitor body disposed in a capacitor case and shielded by a potting resin, the capacitor terminal member projecting from a potting surface of the capacitor body. The capacitor is fixed to the capacitor case such that the potting surface faces the semiconductor module. The capacitor terminal member is supported by and fixed to a fixing/supporting member fixed to the apparatus case.

This application claims priority to Japanese Patent Application No. 2012-256453 filed on Nov. 22, 2012, and No. 2013-153612 filed on Jul. 24, 2013, the entire contents of which are hereby incorporated by reference.

### BACKGROUND OF THE INVENTION

1. Field of the Invention

The present invention relates to a power conversion apparatus including semiconductor modules, a capacitor connected to the semiconductor modules and an apparatus case housing the semiconductor modules and the capacitor.

2. Description of Related Art

It is known to equip an electric vehicle or a hybrid vehicle with a power conversion apparatus such as an inverter or a converter, which includes semiconductor modules and a capacitor housed in an apparatus case. The main electrode terminals of the semiconductor modules may be electrically connected to capacitor terminal members of the capacitor by welding or the like.

The capacitor may include a capacitor body having a capacitor element sealed by potting resin and housed in a capacitor case, the capacitor terminal members projecting from the potting surface of the capacitor body. For example, refer to Japanese Patent Application Laid-open No. 2010-251400. To house such a capacitor in the apparatus case, it is necessary to fix the capacitor case to the apparatus case by a fastening member. Further, to locate the capacitor terminal members so as to extend toward the main electrodes of the semiconductor modules, it is necessary to dispose the capacitor such that the potting surface faces the semiconductor modules.

However, for the potting surface to face the semiconductor modules, the capacitor has to be disposed such that the potting surface is perpendicular to its mounting surface in the apparatus case. In this case, since the capacitor body cannot be fixed to the apparatus case by the fastening member at the side of the potting surface, the fastening member has to be disposed at a surface other than the potting surface. In this structure, it is difficult to suppress the capacitor from vibrating in a direction to slump to the potting surface against vibration transmitted from the outside to the power conversion apparatus. That is, there is a concern that the vibration of the capacitor in the direction to slump to the pointing surface may increase, causing stress concentration in the connecting portion between the capacitor terminal members and the main electrodes of the semiconductor modules.

The semiconductor modules and the capacitor are fixed at predetermined positions within the apparatus case. The capacitor is fixed to the apparatus case through the capacitor case. However, the capacitor terminal members are not directly fixed to the apparatus case because, between the apparatus case and the capacitor terminal members, the capacitor case, the potting surface and the capacitor element are interposed. Accordingly, even if the positioning accuracy of each of these components is kept high, the capacitor terminal members are likely to be displaced relative to the apparatus case due to accumulation of the position aberration among these components.

As a result, a positional displacement may occur between the capacitor terminal members and the main electrodes fixed to the apparatus case separately from the capacitor. In this case, it may be difficult to establish a stable connection between the capacitor terminal members and the main electrodes.

### SUMMARY

An exemplary embodiment provides a power conversion apparatus including:

at least one semiconductor module including a main electrode terminal;

a capacitor including at least one capacitor terminal member connected to the main electrode terminal of the semiconductor module; and

an apparatus case housing the semiconductor module and the capacitor,

wherein

the capacitor includes a capacitor body disposed in a capacitor case and shielded by a potting resin, the capacitor terminal member projecting from a potting surface of the capacitor body,

the capacitor is fixed to the capacitor case such that the potting surface faces the semiconductor module, and

the capacitor terminal member is supported by and fixed to a fixing/supporting member fixed to the apparatus case.

According to the exemplary embodiment, there is provided a power conversion apparatus in which the positional accuracy between the capacitor terminal member and the main electrode terminal of the semiconductor module can be made high, and the stress occurring in the connecting portion therebetween can be reduced.

Other advantages and features of the invention will become apparent from the following description including the drawings and claims.

### BRIEF DESCRIPTION OF THE DRAWINGS

In the accompanying drawings:

FIG. 1 is a plan view of a power conversion apparatus according to a first embodiment of the invention;

FIG. 2 is a cross-sectional view taken along line II-II of FIG. 1;

FIG. 3 is a cross-sectional view taken along line III-III of FIG. 1;

FIG. 4 is a graph showing a stress suppression effect by a connecting portion of the power conversion apparatus according to the first embodiment of the invention;

FIG. 5 is a cross-sectional view of a power conversion apparatus according to a second embodiment of the invention;

FIG. 6 is a cross-sectional view of a power conversion apparatus according to a third embodiment of the invention;

FIG. 7 is a cross-sectional view of a modification of the power conversion apparatus according to the third embodiment of the invention;

FIG. 8 is a cross-sectional view of a power conversion apparatus according to a fourth embodiment of the invention;

FIG. 9 is a cross-sectional view of a modification of the power conversion apparatus according to the fourth embodiment of the invention;

FIG. 10 is a plan view of a power conversion apparatus according to a fifth embodiment of the invention;

FIG. 11 is a cross-sectional view taken along line XI-XI of FIG. 10;

FIG. 12 is a cross-sectional view taken along line XII-XII of FIG. 10;

FIG. 13 is a plan view of a positive capacitor terminal member of the power conversion apparatus according to the fifth embodiment of the invention;

FIG. 14 is a perspective view of the positive capacitor terminal member of the power conversion apparatus according to the fifth embodiment of the invention;

FIG. 15 is a plan view of one of plate-like members constituting the positive capacitor terminal member of the power conversion apparatus according to the fifth embodiment of the invention;

FIG. 16 is a plan view of the other of the plate-like members constituting the positive capacitor terminal member of the power conversion apparatus according to the fifth embodiment of the invention;

FIG. 17 is a plan view of the one of the plate-like members constituting the positive capacitor terminal member before being bent;

FIG. 18 is a plan view of the other of the plate-like members constituting the positive capacitor terminal member before being bent;

FIG. 19 is a plan view of a negative capacitor terminal member of the power conversion apparatus according to the fifth embodiment of the invention;

FIG. 20 is a perspective view of the negative capacitor terminal member of the power conversion apparatus according to the fifth embodiment of the invention;

FIG. 21 is a plan view of one of plate-like members constituting the negative capacitor terminal member;

FIG. 22 is a plan view of the other of the plate-like members constituting the negative capacitor terminal member;

FIG. 23 is a plan view of the one of the plate-like members constituting the negative capacitor terminal member before being bent; and

FIG. 24 is a plan view of the other of the plate-like members constituting the negative capacitor terminal member before being bent.

### PREFERRED EMBODIMENTS OF THE INVENTION

In the below described embodiments, the same or equivalent parts or components are indicated by the same reference numerals or characters.

First Embodiment

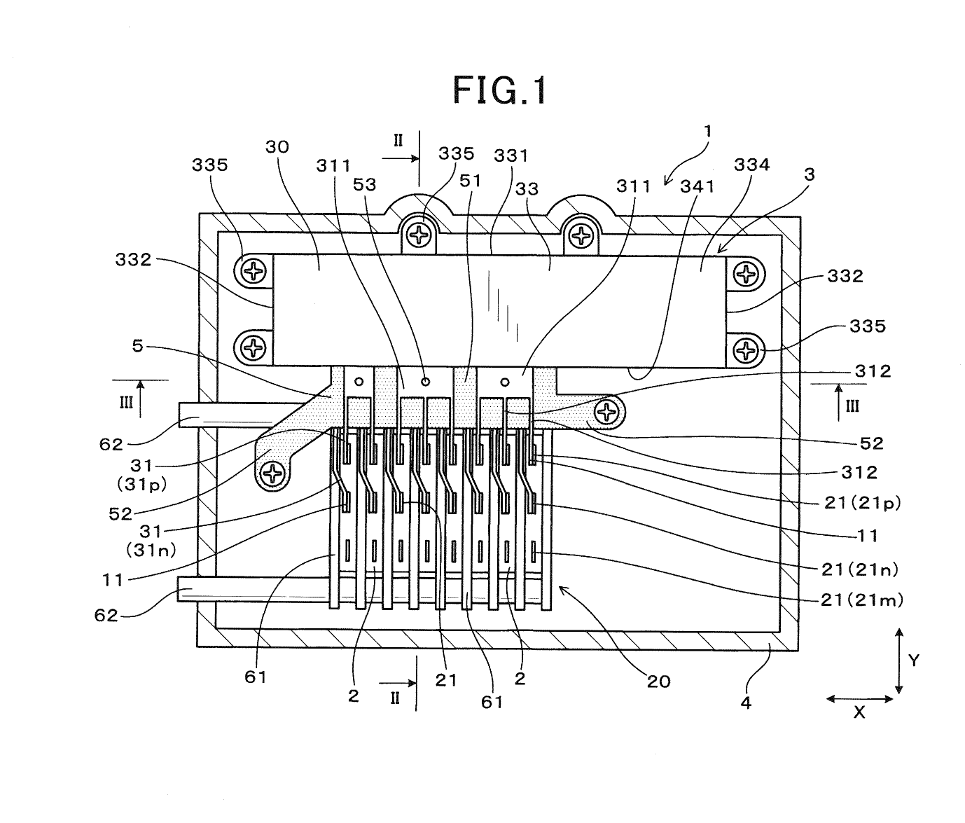

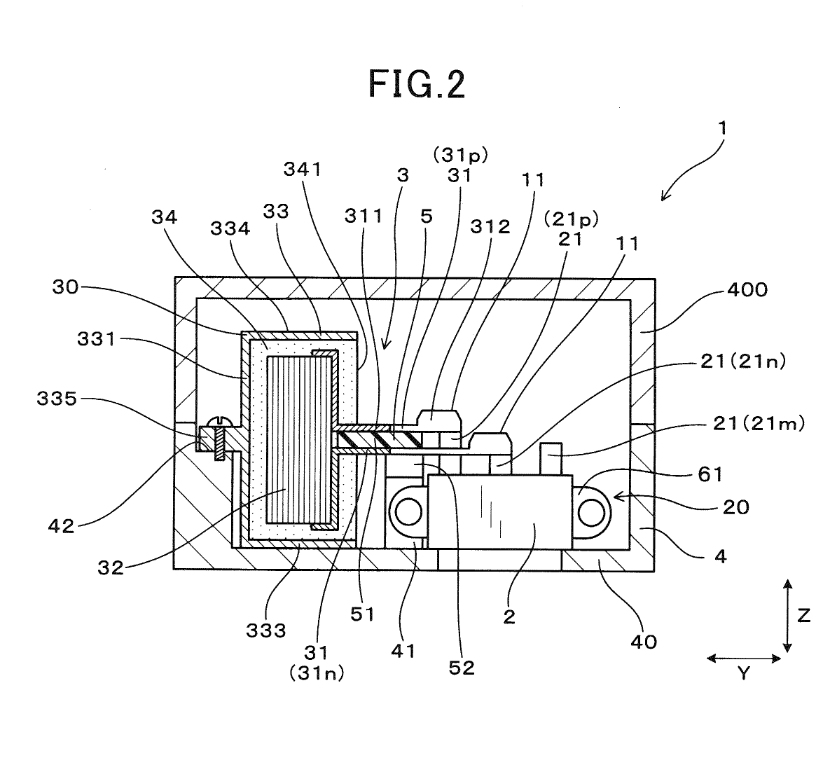

A power conversion apparatus 1 according to a first embodiment of the invention is described with reference to FIGS. 1 to 4. As shown in FIGS. 1 and 2, the power conversion apparatus 1 includes semiconductor modules 2 each having main electrode terminals 21, a capacitor 3 having capacitor terminal members 31 connected to the main electrode terminals 21 of the semiconductor modules 2, and an apparatus case 4 housing the semiconductor modules 2 and the capacitor 3.

As shown in FIG. 2, the capacitor 3 includes a capacitor body 30 having capacitor element 32s each sealed by a potting resin 34 and disposed inside a capacitor case 33, and the capacitor terminal members 31 projecting from a potting surface 341 of the capacitor body 30. The capacitor 3 is fixed to the apparatus case 4 through the capacitor case 33 such that the potting surface 341 faces the semiconductor modules 2.

The capacitor terminal members 31 are supported by and fixed to a supporting/fixing member 5 fixed to the apparatus case 4. The supporting/fixing member 5 supports and fixes the capacitor terminal members 31 between the capacitor body 30 and a connecting portion 11 between the main electrode terminals 21 of the semiconductor modules 2 and the capacitor terminal members 31.

As shown in FIG. 1, the power conversion apparatus 1 of this embodiment has a structure in which the semiconductor modules 2 and cooling tubes 61 for cooling the semiconductor modules 2 are stacked alternately so as to form a stacked body 20. Each of the cooling tubes 61 has a coolant passage through which coolant flows in the passage direction (may be referred to as “the lateral direction Y” hereinafter) perpendicular to the stacking direction of the stacked body 20 (may be referred to as “the stacking direction X” hereinafter) . Each adjacent two of the cooling tubes 61 are connected at their both ends in the passage direction (lateral direction Y). The cooling tube 61 located at one end in the stacking direction X of the stacked body 20 includes a pair of coolant inlet/outlet tubes 62 extending in the stacking direction X.

Each of the semiconductor modules 2 incorporates a plurality of switching elements such as IGBTs constituting a power conversion circuit, and has the main electrode terminals 21 which are three in number and projecting outward. As shown in FIG. 2, the main electrode terminals 21 project in the direction perpendicular to both the stacking direction X and the lateral direction Y (which may be referred to as the “height direction Z” hereinafter).

The capacitor 3 is disposed in the apparatus case 4 so as to adjoin one of the sides in the lateral direction Y of the stacked body 20. The capacitor body 30 is fixed inside the apparatus case 4 such that the opening plane of the capacitor case 33, that is the potting surface 341 of the potting resin 34 faces the stacked body 20. The capacitor terminal members 31 project from the potting surface 341 toward the stacked body 20, and connected to the main electrode terminals 21 of the semiconductor modules 2.

As shown in FIG. 2, the capacitor terminal members 31 of the capacitor 3 include positive capacitor terminal members 31p and negative capacitor terminal members 31n. A part of the supporting/fixing member 5 constitutes a plate-like insulating portion 51 disposed between the positive capacitor terminal members 31p and the negative capacitor terminal members 31n for electrically insulating them from each other.

Another part of the supporting/fixing member 5 is molded into the potting resin 34. That is, the insulating portion 51 is partly disposed inside the potting resin 34 together with the positive capacitor terminal member 31p and the negative capacitor terminal member 31n. The supporting/fixing member 5 may be made of a resin material such as PPS (polyphenylene sulfide).

The supporting/fixing member 5 includes leg portions 52 at both ends of the insulating portion 51, and fixed to the apparatus case 4 at the leg portions 52 by screws. That is, as shown in FIG. 1, the insulating portion 51 has a shape elongated in the stacking direction X, and is formed with the leg portions at its both ends in the longitudinal direction thereof. The supporting/fixing member 5 is fixed to the apparatus case 4 by screwing the leg portions 52 to bosses 41 formed in the apparatus case 4.

The supporting/fixing member 5 is also swaged to the capacitor terminal members 31. More specifically, the supporting/fixing member 5 includes projections 53 formed in the insulating portion 51 so as to project toward both sides in the height direction Z, and these projections 53 are swaged into holes formed in the capacitor terminal members 31. In this way, the supporting/fixing member 5 and the capacitor terminal members 31 (the positive and negative capacitor terminal members 31p and 31n) located at both surfaces of the supporting/fixing member 5 are fixed to each other.

As shown in FIGS. 1 and 2, the capacitor case 33 has a roughly rectangular parallelepiped which opens at the potting surface 341. The capacitor case 33 includes a back wall portion 331 opposite to the potting surface 341, a pair of lateral wall portions located at both ends thereof in the stacking direction X, and top and bottom wall portions 333 and 334 located at both ends thereof in the height direction Z. The capacitor case 33 is mounted such that the bottom wall portion 333 is disposed at the side of the mounting surface thereof within the apparatus case 4.

The capacitor case 33 includes fastening portions 335 formed in the back wall portion 331 and the lateral wall portions 332. The fastening portions 335 are shaped so as to project at a right angle from the surfaces of the respective wall portions. Each of the fastening portions 335 is located at an intermediated position between both ends in the height direction Z of the capacitor case 33.

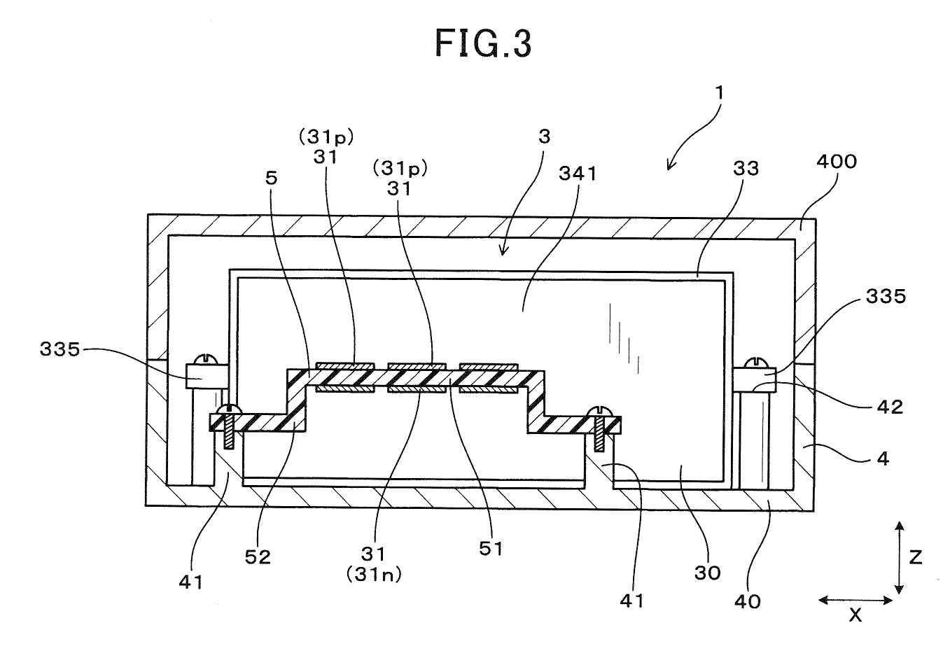

The capacitor case 33 is fixed to the apparatus case 4 at the fastening portions 335 by screws. More specifically, as shown in FIGS. 2 and 3, the apparatus case 4 includes seat surfaces 42 formed in the end surfaces of bosses or the like, and the fastening portions 335 are seated on and fastened to the seat surfaces by screws. In this way, the capacitor case 33 is fixed to the apparatus case 4, and accordingly the capacitor 3 is fixed to the case 4.

As shown in FIGS. 1 and 2, each semiconductor module 2 includes, as the three main electrode terminals 21, a positive terminal 21p connected to the positive capacitor terminal member 31p, a negative terminal 21n connected to the negative capacitor terminal member 31n and output terminal 21m to be connected to an electrical load such as an electric rotating machine.

The capacitor 3 includes a plurality of the capacitor elements 32, electrodes of each of which are connected with a corresponding one of pairs of the capacitor terminal members 31. As shown in FIG. 1, each capacitor terminal member 31 includes a terminal body 311 partly embedded in the potting resin 34, and a plurality of comb-shaped portions 312 each including two or three teeth projecting from the terminal body 311. The capacitor terminal members 31 are connected to the main electrode terminals 21 of the semiconductor modules 2 at the ends of their comb-shaped portions 312 by welding such as laser welding so as to form the connecting portions 11.

As shown in FIGS. 2 and 3, the apparatus case 4 includes a case body 40 on which the stacked body 20 and the capacitor 30 are mounted, and a case lid 400 that covers the case body 40 at the side in which the main electrode terminals 21 of the semiconductor modules 2 project. The case lid 400 is fixed to the case body 40 by bolts or the like. Although not shown in the drawings, the case apparatus 4 includes a case member at the other side of the case lid 400.

The power conversion apparatus 1 having the above described structure is mounted on a vehicle such as an electric vehicle or a hybrid vehicle to drive an AC electric rotating machine serving as a motor of the vehicle.

The first embodiment described above provides the following advantages. The capacitor terminal members 31 are supported by and fixed to the supporting/fixing member 5 which is fixed to the apparatus case 4. Accordingly, the capacitor 3 can be suppressed from vibrating relative to the apparatus case 4 when the capacitor 3 is subjected to vibration from the outside. This is because since the capacitor terminal members 31 are supported by and fixed to the supporting/fixing member 5, it is possible to suppress the capacitor 3 from vibrating in the direction to slump to the potting surface 341. Accordingly, since the capacitor terminal members 31 and the main electrode terminals 21 can be suppressed from vibrating relative to each other, the stress occurring in the connecting portions 11 can be reduced. Hence, the durability of connection between the capacitor 3 and the semiconductor modules 2 can be improved.

Since the capacitor terminal members 31 are supported by and fixed to the supporting/fixing member 5 which is fixed to the apparatus case 4, the positioning accuracy between the capacitor terminal members 31 and the main electrode terminals 21 of the semiconductor modules 2 can be improved. That is, by fixing the capacitor terminal members 31 to the apparatus case 4 through the supporting/fixing member 5, the positional deviation between the apparatus case 4 and the capacitor terminal members 31 can be made smaller than the sum of the positional deviation between the apparatus case 4 and the supporting/fixing member 5 and the positional deviation between the supporting/fixing member 5 and the capacitor terminal members 31. As a result, the positional accuracy between the capacitor terminal members 31 and the main electrode terminals 21 of the semiconductor modules 2 can be improved. Hence, in the power conversion apparatus 1 according to this embodiment, the connection between the capacitor terminal members 31 and the main electrode terminals 21 is stable and reliable.

Further, since the supporting/fixing member 5 supports and fixes the capacitor terminal members 31 between the connecting portions 11 and the capacitor body 30, the stress occurring in the connecting portions 11 can be effectively reduced. Apart of the supporting/fixing member 5 intervenes between the positive capacitor terminal members 31p and the negative capacitor terminal members 31n, and forms the insulating portion 51 for electrical insulation therebetween. This makes it possible that the supporting/fixing member 5 serves as both a means for suppressing vibration of the capacitor terminal members 31 and a means for providing insulation between the positive capacitor terminal members 31p and the negative capacitor terminal members 31n. This makes it possible to suppress the stress in the connecting portions 51 while reducing the parts count of the power conversion apparatus .

Since a part of the supporting/fixing member 5 is molded into the potting resin 34, vibration of the capacitor 3 can be suppressed easily by the supporting/fixing member 5, to facilitate reduction of the stress in the connecting portions 11. Further, the positive capacitor terminal members 31p and the negative capacitor terminal members 31n can be reliably electrically insulated from each other by the supporting/insulating member 5.

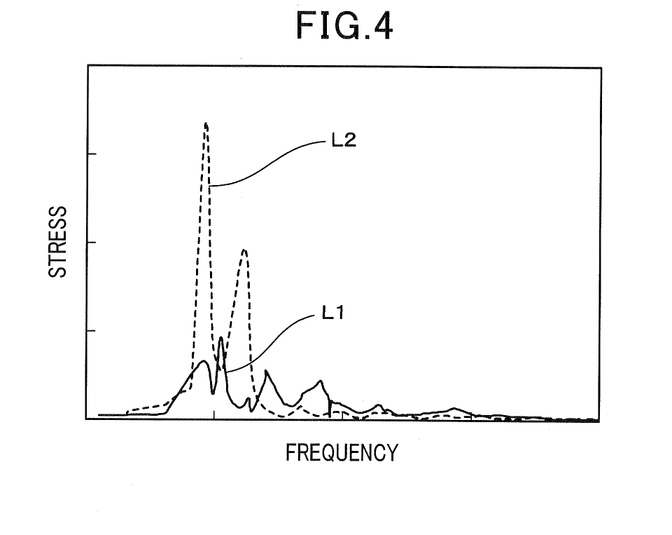

FIG. 4 is a graph showing the stress suppression effect for the connecting portions 11 of the power conversion apparatus 1 according to this embodiment of the invention. The curve L1 in FIG. 4 represents variation of the stress intensity in the connecting portions 11 when the frequency of vibration applied to the power conversion apparatus 1 provided with the supporting/fixing member 5 is gradually changed. The curve L2 in FIG. 4 represents variation of the stress intensity in the connecting portions 11 when the frequency of vibration applied to the power conversion apparatus 1 not provided with the supporting/fixing member 5 is gradually changed. As seen from FIG. 4, if the supporting/fixing member 5 is not provided (L2), the stress intensity in the connecting portions 11 becomes extremely high at some frequencies. On the other hand, in this embodiment (L1), the magnitude of the peak stress intensity is reduced to approximately one fourth of that in the case where the supporting/fixing member 5 is not provided.

As described above, according to the first embodiment of the invention, it is possible to improve the positioning accuracy between the capacitor terminal members and the main electrode terminals of the semiconductor modules, to thereby reduce the stress occurring therebetween.

### Second Embodiment

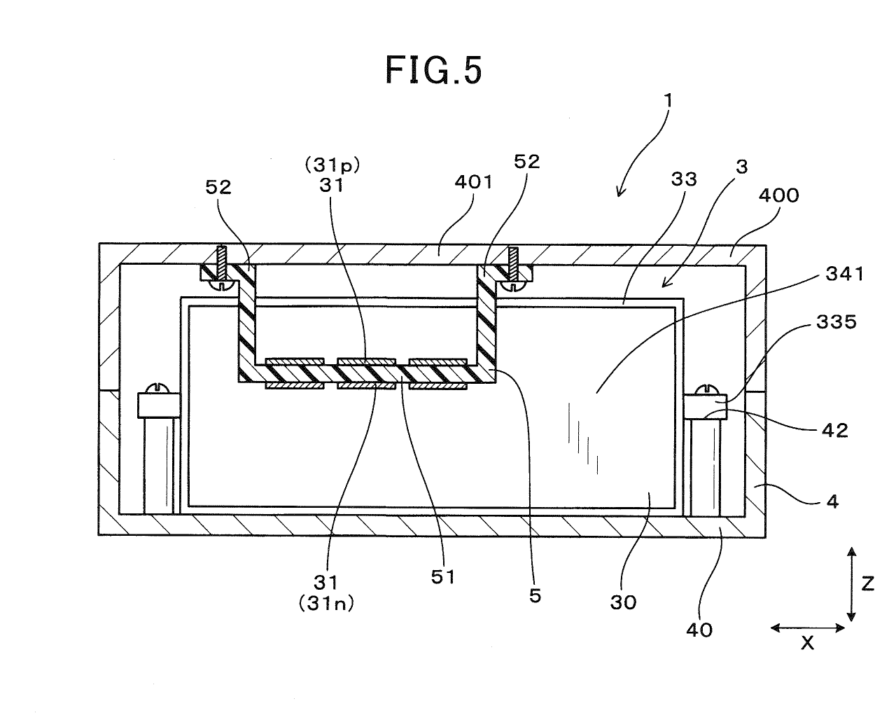

FIG. 5 is a cross-sectional view of a power conversion apparatus according to a second embodiment of the invention. As shown in FIG. 5, in the second embodiment, the leg portions 52 of the supporting/fixing member 5 are fixed to the case lid 400 of the apparatus case 4. That is, in the second embodiment, the capacitor terminal members 31 are fixed to the case lid 400 of the apparatus case 4 through the support/fixing member 5. The pair of the leg portions 52 of the support/fixing member 5 are fastened to the inner surface of a ceiling plate 401 of the case lid 400 by screws or the like. Other than the above, the second embodiment is the same as the first embodiment.

The second embodiment has a high degree of flexibility in the fixing position of the leg portions 52 of the support/fixing member 5 relative to the apparatus case 4. Other than the above, this embodiment provides the same advantages as those provided by the first embodiment.

### Third Embodiment

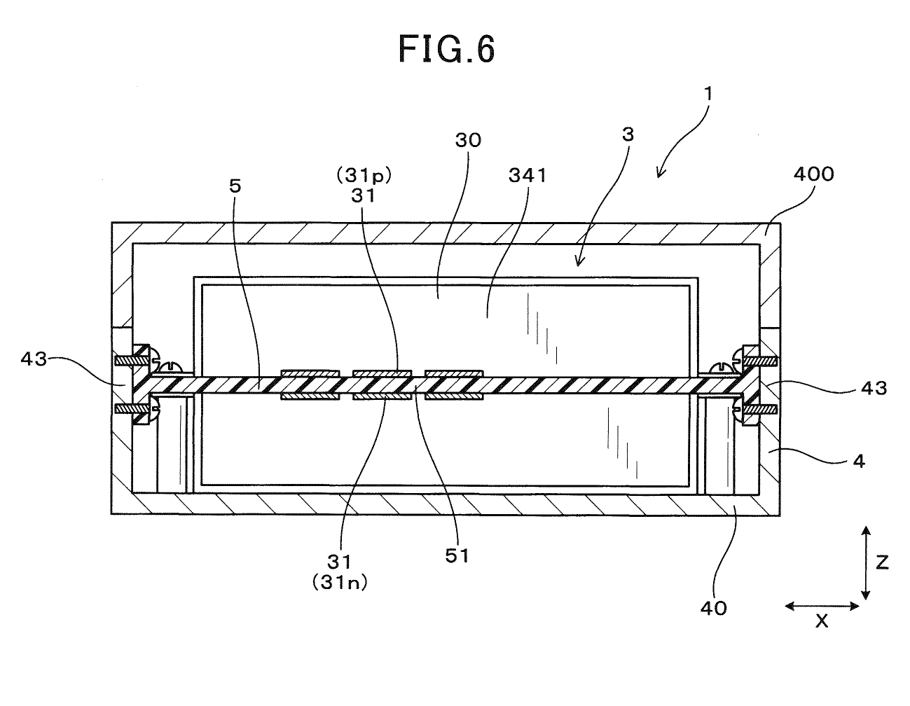

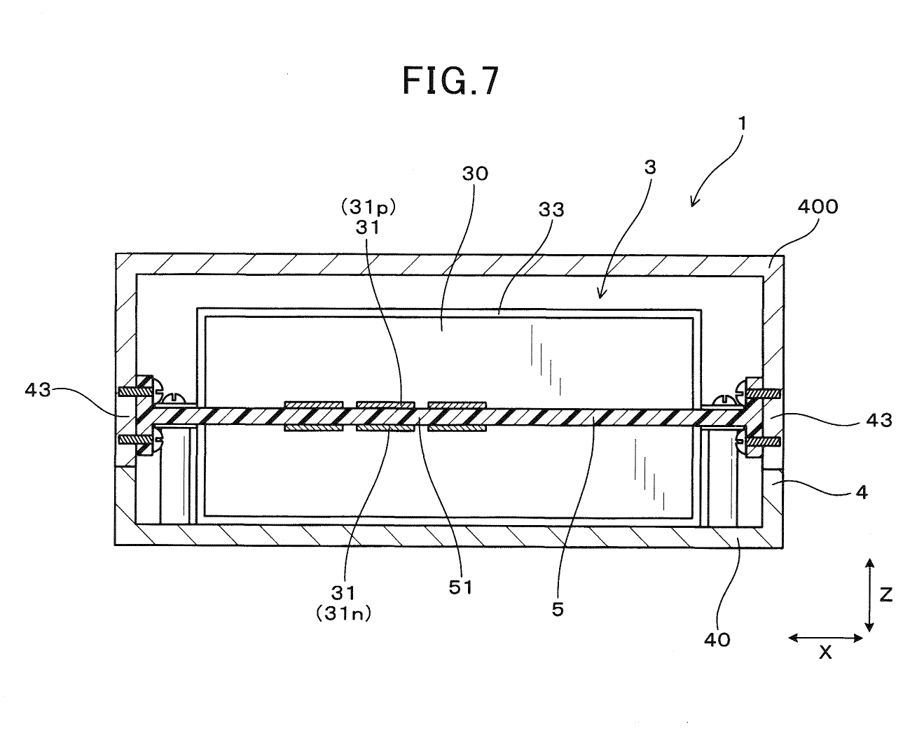

FIG. 6 is a cross-sectional view of a power conversion apparatus according to a third embodiment of the invention. FIG. 7 is a cross-sectional view of a modification of the power conversion apparatus according to the third embodiment of the invention. As shown in FIGS. 6 and 7, in the third embodiment, the supporting/fixing member 5 is fixed to the inner surfaces of side plates 43 of the apparatus case 4. In this embodiment, the supporting/fixing member 5 extends in the stacking direction X, and abuts on the inner surfaces of the side plates 43 of the apparatus case 4 at both ends thereof. The supporting/fixing member 5 is fixed to the side plates 43 at the abutting portions by screws or the like.

As shown in FIG. 6, the side plates 43 to which the supporting/fixing member 5 is fixed may be included in the case body 40, or in the case lid 400.

Other than the above, the third embodiment is the same as the first embodiment. Other than the above, this embodiment provides the same advantages as those provided by the first embodiment.

### Fourth Embodiment

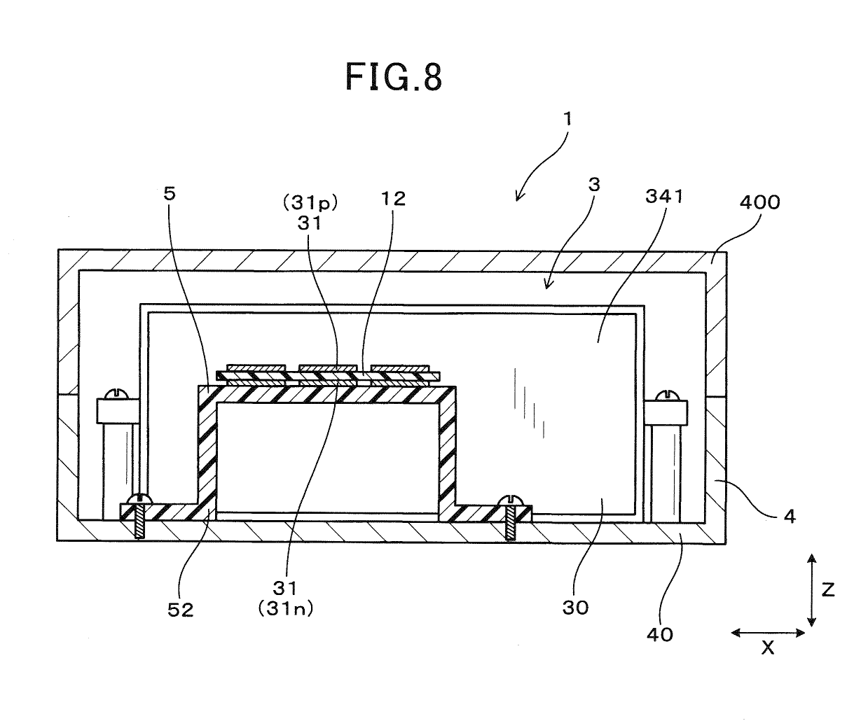

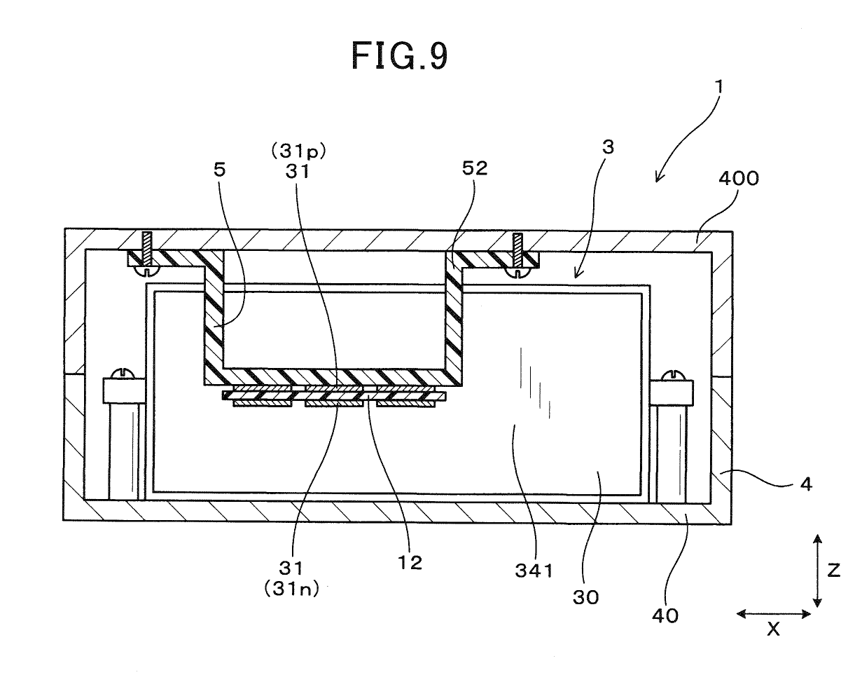

FIG. 8 is a cross-sectional view of a power conversion apparatus according to a fourth embodiment of the invention. FIG. 9 is a cross-sectional view of a modification of the power conversion apparatus according to the fourth embodiment of the invention. As shown in FIGS. 8 and 9, in the fourth embodiment, the supporting/fixing member 5 does not have the function of electrically insulating the positive capacitor terminal members 31p and the negative capacitor terminal members 31n from each other, and instead, an insulating member 12 is provided for electrically insulating the positive capacitor terminal members 31p and the negative capacitor terminal members 31n from each other.

That is, in this embodiment, the insulating member 12 made of insulating paper or the like is interposed between the positive capacitor terminal members 31p and the negative capacitor terminal members 31n. The supporting/fixing member 5 is disposed such that a part thereof faces the insulating member 12 across from the positive capacitor terminal members 31p or the negative capacitor terminal members 31 between the capacitor body 30 and the connecting portions 11, and is fixed to the capacitor terminal members 31.

The leg portions 52 of the supporting/fixing member 5 are fixed to the apparatus case 4. The leg portions 52 of the supporting/fixing member 5 may be fixed to the case body 40 as shown in FIG. 8, or to the case lid 400 as shown in FIG. 9.

Other than the above, the fourth embodiment is the same as the first embodiment, and provides the same advantages as those provided by the first embodiment.

### Fifth Embodiment

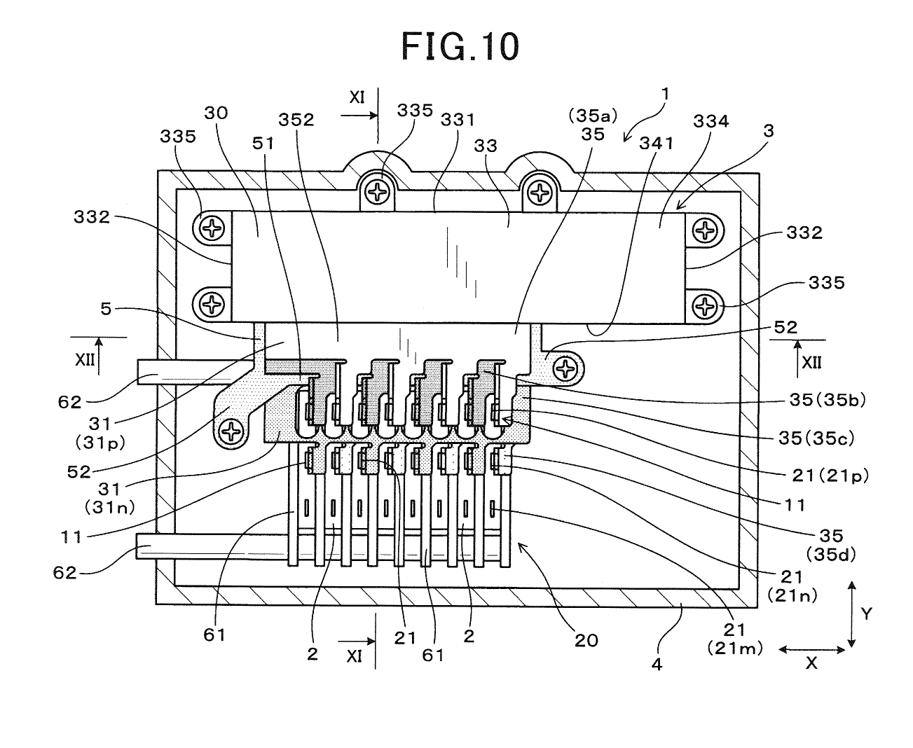

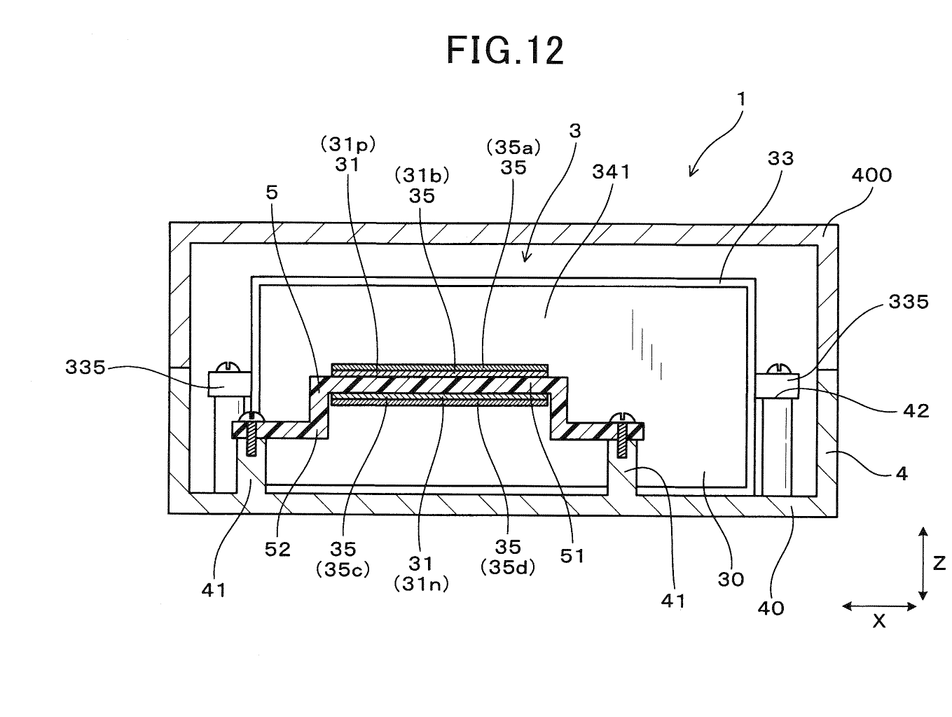

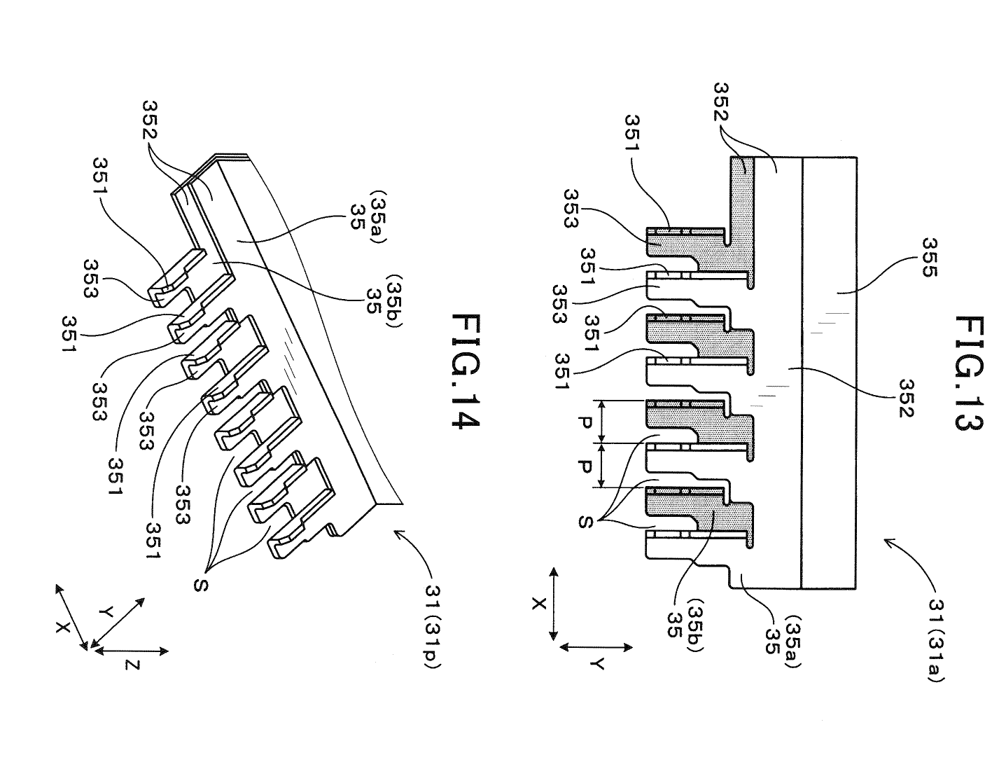

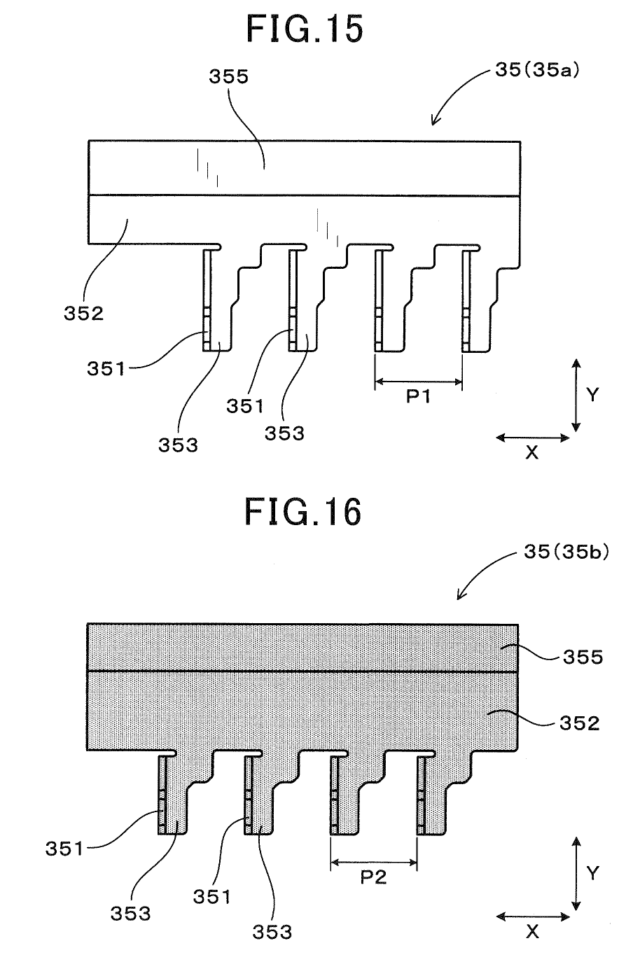

Next, a fifth embodiment of the invention is described with reference to FIGS. 10 to 24. As shown in FIGS. 10 to 24, in the fifth embodiment, the capacitor terminal members 31 are made of a plurality of plate-like members 35 stacked on one another. As shown in FIGS. 15, 16, 21 and 22, each plate like member 35 includes a plurality of terminal portions 351 connected to the main electrode terminals 21 of the semiconductor modules 2. As shown in FIGS. 13, 14, 19 and 20, each adjacent two in the stacking direction of the terminal portions 351 are provided in different ones of the plate-like members 35, respectively. That is, the capacitor terminal members 31 are provided such that the terminal portions 351 of the same plate-like member 35 do not adjoin to each other in the stacking direction X.

Each plate-like member 35 includes a plate-like body 352, extension portions 353 branching from the plate-like body 35 and the terminal portions 351 formed at the ends of the extension portions 353. As shown in FIGS. 10 to 12, the plate-like body 352 is disposed such that the main surface thereof is perpendicular to the projecting direction (height direction Z) of the main electrode terminals 21 of the semiconductor modules 2. The extension portion 353 projects in the direction perpendicular to both the stacking direction X and the projecting direction (height direction Z), that is, in the lateral direction Y. As shown in FIGS. 13, 14, 19 and 20, the capacitor terminal members 31 are made up by stacking the plate-like bodies 352. As shown in FIG. 10, the terminal portions 351 are connected to the main electrode terminals 21 of the semiconductor module 2 in a state of being overlapped in the stacking direction X.

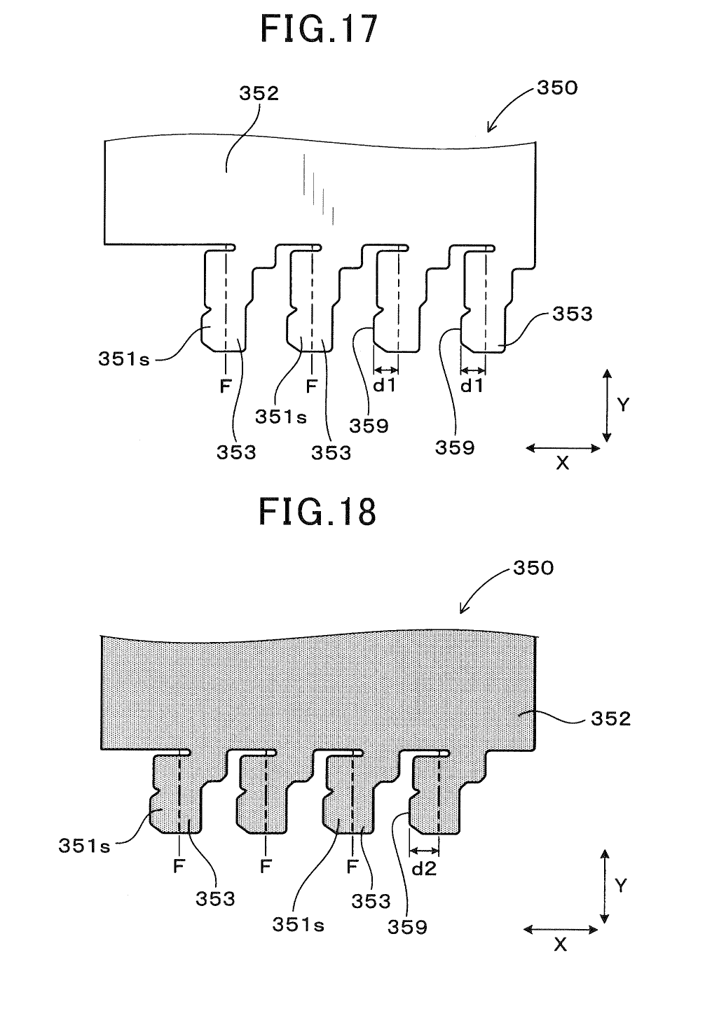

As shown in FIGS. 17, 18, 23 and 24, to manufacture the plate-like member 35, there is prepared an unbent member 350 made of a metal plate and not bent between a portion to form the terminal portion 351 (the “terminal portion forming portion 351s” hereinafter) and the extension portion 353. The unbent member 350 is bent along a bending line F extending in parallel to the lateral direction Y between the terminal portion forming portion 351s and the extension portion 353, so that the terminal portion forming portion 351s makes the terminal portion 351.

Next, the positive capacitor terminal members 31p constituting the capacitor terminal members 31 together with the negative capacitor terminal members 31n are explained in detail with reference to FIGS. 14 to 18. The positive capacitor terminal members 31p are formed by two plate-like members 35a and 35b. The pitch P1 (see FIG. 15) of the terminal portions 351 of the plate-like member 35a is equal the pitch P2 (see FIG. 16) of the terminal portions 351 of the plate-like member 35b. As shown in FIGS. 17 and 18, the dimension d1 in the stacking direction X of the terminal portion forming portion 351s of one of the unbent members 350 is smaller by the thickness of the plate-like body 352 than the dimension d2 in the stacking direction X of the terminal portion forming portion 351s of the other of the unbent members 350. Accordingly, the positions of end surfaces 359 of all of the terminal portions 351 are aligned in the height direction Z when the positive capacitor terminal members 31p are formed by laying the two plate-like members 40a and 41a on each other (see FIG. 14).

As shown in FIG. 13, a gap S is present between the terminal portions 351 of the plate-like members 35a and the extension portions 353 of the plate-like member 35b when the two plate-like members 35a and 35b are laid on each other. A gap S is present also between the terminal portions 351 of the plate-like members 35b and the extension portions 353 of the plate-like member 35a. The main electrode terminals 21 are disposed in these gap S (see FIG. 10).

The pitch P of the terminal portions 351 in the combination of the plate-like members 35a and 35b (see FIG. 13) is equal to a half of the individual pitches P1 and P2 of the terminal portions 351 of the plate-like member 35a and 35b (see FIGS. 15 and 16).

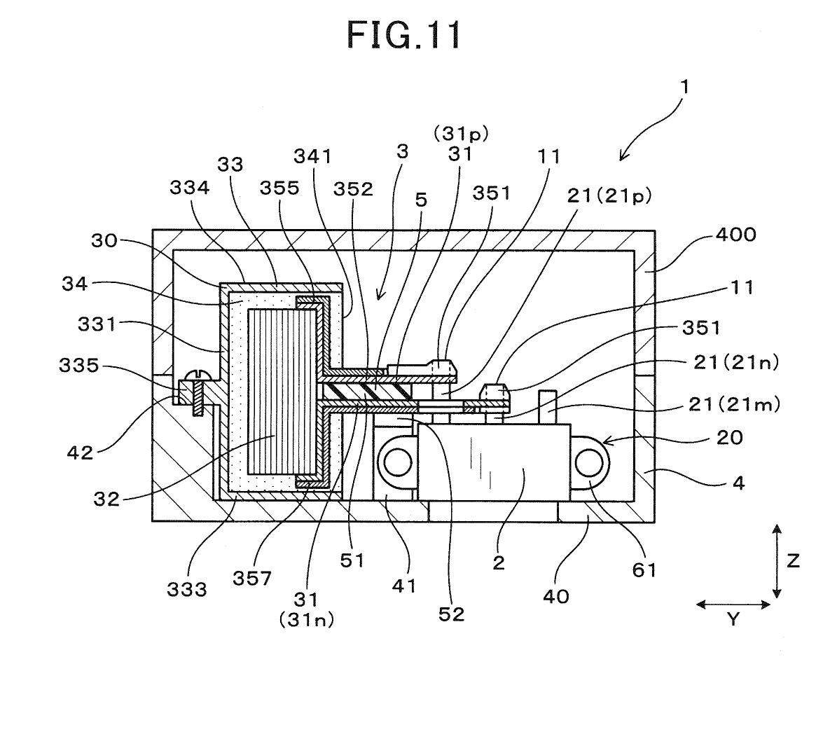

As shown in FIG. 13, the plate-like body 352 of each of the plate-like members 35a and 35b is formed with a capacitor connecting portion 355 having a stepwise-bent shape at the side opposite to the extension portions 353. As shown in FIG. 11, the capacitor connecting portions 355 are connected to the positive electrode of the capacitor elements 32.

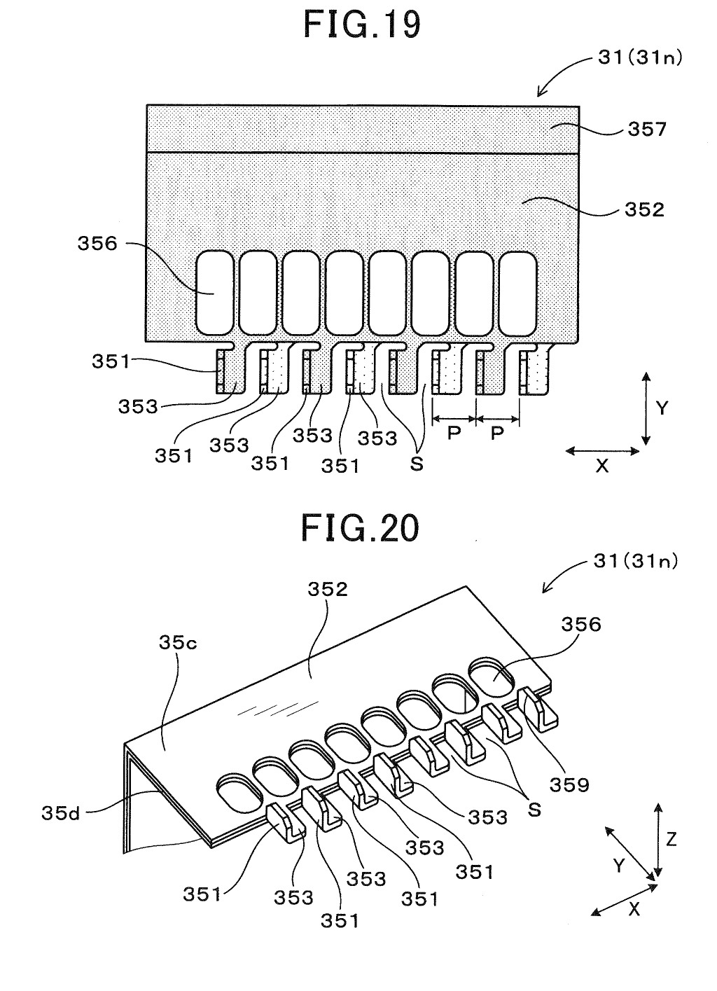

Next, the negative capacitor terminal members 31n are explained in detail with reference to FIGS. 19 to 24. The negative capacitor terminal members 31n are formed of plate-like members 35c and 35d each having a plate-like body 352. The plate-like bodies 352 of the plate-like members 35c and 35d have the same shape. These plate-like bodies 352 is formed with a plurality of through holes 356 through which the main electrode terminals 21 pass (see FIG. 10).

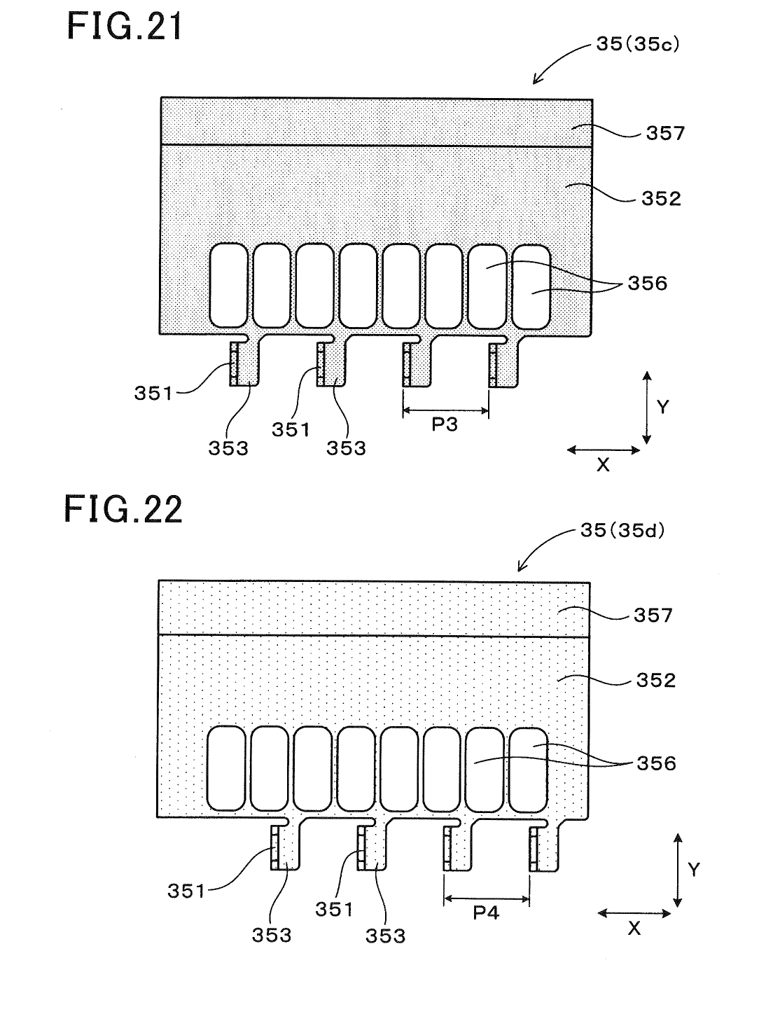

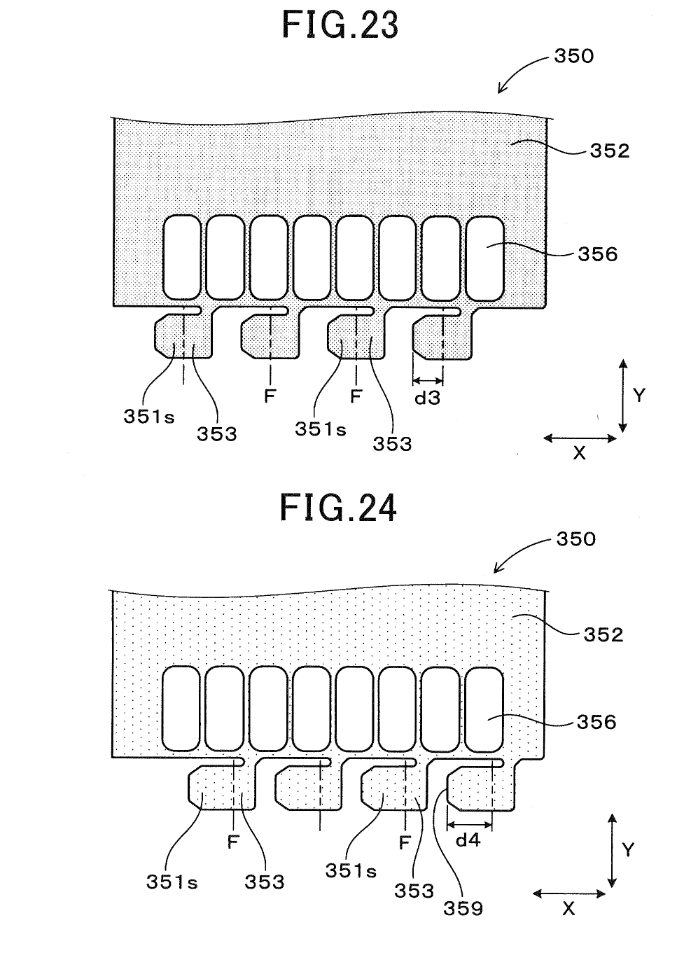

As shown in FIGS. 21 and 22, the pitch P3 of the terminal portions 351 of the plate-like member 35c is equal to the pitch P4 of the terminal portions 351 of the plate-like member 35d. As shown in FIGS. 23 and 24, the dimension d3 in the stacking direction X of the terminal portion forming portion 351s of one of the unbent members 350 is smaller by the thickness of the plate-like body 352 than the dimension d4 in the stacking direction X of the terminal portion forming portion 351s of the other of the unbent members 350. Accordingly, the positions of end surfaces 359 of all of the terminal portions 351 are aligned in the height direction Z when the negative capacitor terminal members 31n are formed by laying the two plate-like members 35c and 35d on each other (see FIG. 20).

As shown in FIGS. 19 and 20, a gap S is present between the terminal portions 351 of the plate-like members 35c and the extension portions 323 of the plate-like member 35d when the two plate-like members 35c and 35d are laid on each other. A gap S is present also between the terminal portions 351 of the plate-like members 35d and the extension portions 353 of the plate-like member 35c. The main electrode terminals 21 are disposed in these gap S (see FIG. 10).

As shown in FIG. 19, the plate-like body 352 of each of the plate-like members 35c and 35d is formed with a capacitor connecting portion 357 having a stepwise-bent shape at the side opposite to the extension portions 353. As shown in FIG. 11, the capacitor connecting portions 357 are connected to the negative electrode of the capacitor elements 32.

Other than the above, the fifth embodiment is the same as the first embodiment.

According to the fifth embodiment, the positional accuracy between the capacitor terminal members 31 (31p and 31n) and the main electrode terminals 21 of the semiconductor modules 2 can be improved. In the case where the capacitor terminal members are constituted of a plurality of the plate-like members 35, positional deviation easily occurs between the apparatus case 4 and part of the capacitor terminal members (part of the terminal portions 351). This is because, since positional deviation may occur also between the plate-like members laid on each other, it is likely that at least one of the plurality of the plate-like members deviates relative to the apparatus case 4. In this embodiment, since the capacitor terminal members 31 are supported and fixed by the supporting/fixing member 5 fixed to the apparatus case 4, the positional deviation between the apparatus case 4 and the capacitor terminal members 31 can be reduced. Accordingly, the positional accuracy between main electrode terminals 21 of the semiconductor modules 2 and the capacitor terminal members 31 can be improved.

Each plate-like member 35 includes the plate-like body 352, the extension portions 353 and the terminal portions 351. The capacitor terminal members 31 are made up by laying the plate-like bodies 352 on each other. The terminal portions 351 are connected to the main electrode terminals 21 of the semiconductor modules 2 in the state of being overlapped with each other in the stacking direction. Accordingly, the capacitor terminal members 31 can be obtained at a high yield, and the connecting portions 11 can be formed stably.

In the fifth embodiment, the capacitor terminal members 31 are constituted of a plurality of the plate-like members 35. Each plate-like member 35 includes the plate-like body 352, the extension portions 352 and the terminal portions 351. The capacitor terminal members 31 are made up by laying the plate-like bodies 352 such that the terminal portions 351 formed in the same plate-like members 35 do not overlap with one another in the stacking direction X. Accordingly, the pitch of the terminal portions 351 in the state where the plate-like members 35 are laid on each other can be made sufficiently small although the pitch of the terminal portions 351 of the individual plate-like members 35 is large. This allows the dimension in the stacking direction X of the extension portion 353 to be sufficiently large. Accordingly, since the extension portions 353 can be prevented from becoming too elongated, it is possible to prevent the extension portions 353 from having a large parasitic inductance.

As shown in FIGS. 15 to 18 and 21 to 24, to manufacture the individual plate-like members 35, the unbent members are manufactured as intermediate members. In the fifth embodiment, since each capacitor terminal member 31 is constituted of a plurality of the plate-like members 35, the pitches P1 to P4 of the individual plate-like members 35 can be made large. Accordingly, the pitches of the terminal portion forming portion 351s of the unbent member 350 also can be made large. As a result, the distance in the stacking direction X between the terminal portion forming portion 351s and the adjacent extension portion 353 can be made large. Hence, it is possible to make the dimension in the stacking direction X of the extension portion 353 sufficiently large, while allowing the dimension in the stacking direction X of the terminal portion forming portion 351s to be sufficiently large. Hence, since the extension portion 353 can be prevented from becoming too elongated, it is possible to prevent the extension portion 353 from having a large parasitic inductance.

Other than the above, this embodiment provides the same advantages as those provided by the first embodiment. In this embodiment, the capacitor terminal member 31 is constituted of two plate-like members 35. However, the capacitor terminal members 31 may be constituted of three or more plate-like members 35 laid on one another. In this embodiment, each of the capacitor connecting portions 355 and 357 is constituted of a plurality of the plate-like members 35 laid on one another. However, this embodiment may be modified such that each of the capacitor connecting portions 355 and 357 is constituted of a single plate-like member 35, and the plate-like body 352 is constituted of a plurality of the plate-like members 35 laid on one another.

In the above embodiments, the supporting/fixing member 5 is made of insulating material. However, it does not necessarily have to be made of insulating material, if electrical insulation between the supporting/fixing member 5 and the capacitor terminal members 31 can be provided by an appropriate way, for example, by forming an insulating film on the surface of the supporting/fixing member 5.

Each of the power conversion apparatuses described in the above embodiments includes a plurality of the semiconductor modules. However, the present invention can be used for a power conversion apparatus including a single semiconductor module.

The apparatus case may be constituted of a plurality of case members fixed to each other, each of which houses the semiconductor module(s), the capacitor and the supporting/fixing member.

The above explained preferred embodiments are exemplary of the invention of the present application which is described solely by the claims appended below. It should be understood that modifications of the preferred embodiments may be made as would occur to one of skill in the art.

What is claimed is:

1. A power conversion apparatus comprising:
at least one semiconductor module including a main electrode terminal;
a capacitor including at least one capacitor terminal member connected to the main electrode terminal of the semiconductor module; and
an apparatus case housing the semiconductor module and the capacitor,
wherein
the capacitor includes a capacitor body disposed in a capacitor case and shielded by a potting resin, the capacitor terminal member projecting from a potting surface of the capacitor body,
the capacitor is fixed to the capacitor case such that the potting surface faces the semiconductor module, and
the capacitor terminal member is supported by and fixed to a fixing/supporting member fixed to the apparatus case.

2. The power conversion apparatus according to claim 1, wherein the supporting/fixing member supports and fixes the capacitor terminal member between the capacitor body and a connecting portion between the main electrode terminal and the capacitor terminal member.

3. The power conversion apparatus according to claim 1, wherein the capacitor terminal member includes a positive capacitor terminal member and a negative capacitor terminal member, and a part of the supporting/fixing member is interposed between the positive capacitor terminal member and the negative capacitor terminal member to so as to form an insulating portion for electrical insulation therebetween.

4. The power conversion apparatus according to claim 3, wherein the part of the supporting/fixing member is molded into the potting resin.

5. The power conversion apparatus according to claim 1, wherein
a plurality of the semiconductor modules are stacked on each other so as to form a stacked bod, and
the capacitor terminal member is constituted of a plurality of plate-like members laid on each other,
each of the plate-like members including a plurality of terminal portions connected to the main electrode terminals of the semiconductor modules,
each adjacent two of the terminal portions in a stacking direction of the stacked body are formed in different ones of the plate-like members, respectively.

6. The power conversion apparatus according to claim 5, wherein
each of the plate-like members includes a plate-like body disposed such that a main surface thereof is perpendicular to a projecting direction of the main electrode terminals of the semiconductor modules, and a plurality of extension portions branching from each of the plate-like bodies and extending in a direction perpendicular to both the stacking direction and the projecting direction,
each of the terminal portions being formed in an end of a corresponding one of the extension portions,
the capacitor terminal member being formed of the plate-like bodies laid on each other,
the terminal portions being connected to the main electrode terminals of the semiconductor modules in a state of being partially overlapped in the stacking direction.
